(19) United States
(12) Patent Application Publication
(10) Pub. No.: US 2026/0328838 A1
(43) Pub. Date: Oct. 22, 2026

(54) PROBER

(71) Applicant: TOKYO SEIMITSU CO., LTD., Tokyo (JP)

(72) Inventor: Hiroo TAMURA, Tokyo (JP)

(21) Appl. No.: 19/468,654

(22) Filed: Feb. 3, 2026

(30) Foreign Application Priority Data
Mar. 6, 2025 (JP) 2025-035211

(51) Int. Cl. G01R 31/28

(52) U.S. Cl. CPC G01R 31/2881; G01R 31/2863; G01R 31/2865; G01R 31/2868

(57) ABSTRACT

A prober according to an embodiment includes a sealing member located between a holding member and a chuck and forming an enclosed space in which probes are arranged, a suction passage connected with a vacuum source via an external pipe to reduce the pressure in the enclosed space, a regulator that adjusts the flow of fluid through the external pipe so that the negative pressure that acting in the enclosed space becomes closer to a set pressure, a gas supply part that supplies dry gas into the enclosed space, and a pressure controller that controls the regulator. The gas supply part supplies dry gas while the regulator is operating. The pressure controller corrects the set pressure depending on the flow rate of dry gas to prevent the fluid from flowing back from the external pipe to the enclosed space while the regulator and the gas supply part are operating.

### CROSS REFERENCE TO RELATED APPLICATION

This application claims priority from Japanese Patent Application No. 2025-035211 filed on Mar. 6, 2025 in the Japan Patent Office, the contents of which being incorporated by reference herein in its entirety.

### BACKGROUND

The present invention relates to probers for testing devices formed on wafers.

A wafer on which a number of devices are formed through front-end processes of semiconductor manufacturing is divided into multiple chips of individual devices in a dicing Prior to the dicing process, probing is performed process, to remove defective devices from the devices on the wafer. Probing is wafer-level testing for testing the electrical characteristics of devices formed on each wafer to determine defective devices. A machine for probing is a prober.

A prober includes a probe card of a plurality of probes. The probes are brought into electrical contact with a test head. A wafer is brought into contact with the probe card, so that the probes touch electrode pads of the devices. Electrical signals are sent from the test head to the devices via the probes to test their electrical characteristics so as to determine whether or not each device is a defective device.

In recent years, with demands for larger and more highly integrated wafers, the number of devices formed on one wafer is increasing. There have therefore been demands for improving the efficiency of testing to increase throughput and reduce costs in semiconductor manufacturing. In this regard, a so-called multi-stage prober (also referred to as a “multi-prober”) in which a plurality of stages of multiple test heads arranged horizontally are provided in the up-down direction has been developed (refer to JP 2018-049989 A). Such a prober can perform testing with a plurality of test heads simultaneously and continuously, which improves the efficiency of testing.

On each of the stages of the multi-prober, a chuck for placing a wafer is provided for each test head, and an alignment unit shared by a plurality of test heads is provided. The alignment unit detachably supports a chuck on which a wafer is placed. For probing, the alignment unit is driven to bring the chuck closer to the test head so that the wafer comes in contact with a probe card. A sealing member is provided between the test head and the chuck, the pressure in an enclosed space formed inside the sealing member is reduced into a negative pressure, so that the wafer together with the chuck is drawn toward and held on a head stage. This enables the chuck to be temporarily separated from the alignment unit, and probing can be continued in this state. Meanwhile, the alignment unit can be moved to another head stage. This can reduce the number of alignment units relative to the number of test heads, which suppresses the manufacturing costs of probers.

Incidentally, probing is performed in view of actual use environments in order to ensure the functionalities of devices, and is therefore performed in a low-temperature environment depending on the specifications of devices. In this case, it is necessary to prevent damage to devices due to dew condensation. The prober of JP 2018-049989 A is therefore devised to lower the dew point by supplying dry gas to the aforementioned enclosed space as necessary.

This prober switches between reduction of pressure in the enclosed space and supply of dry gas. It is therefore difficult to stably keep the negative pressure state while stably filling the enclosed space with dry gas. In addition, even with the sealing member, it is difficult to completely eliminate pressure leakage from the enclosed space to adjacent spaces (areas with higher vacuum). If the negative pressure in the enclosed space increases owing to the pressure leakage, air may enter the enclosed space, causing dew condensation.

### SUMMARY

The present invention has been made in view of the aforementioned circumstances, and one object thereof is to provide a prober capable of stably preventing occurrence of dew condensation during probing.

A prober according to an aspect includes: a holding member that holds a probe card; a chuck having a suction surface for vacuum suction of a wafer on a face facing the probe card; a sealing member that is located between the holding member and the chuck and forms an enclosed space in which probes connected with the probe card are arranged; a suction passage connected with a vacuum source via an external pipe to reduce a pressure in the enclosed space; a regulator that is connected with the external pipe, and adjusts a flow of fluid through the external pipe so that a negative pressure acting in the enclosed space becomes closer to a set pressure; a gas supply part that supplies dry gas into the enclosed space; and a pressure controller that controls the regulator. The enclosed space is brought into a negative pressure state, so that airtightness of the enclosed space sealed by the sealing member is achieved and the chuck is held by the holding member. The gas supply part supplies dry gas while the regulator is operating. The pressure controller corrects the set pressure depending on a flow rate of the dry gas so as to prevent the fluid from flowing back from the external pipe to the enclosed space while the regulator and the gas supply part are operating.

### BRIEF DESCRIPTION OF DRAWINGS

FIG. 1 is a diagram illustrating a schematic configuration of a prober according to an embodiment;

FIG. 2 is a horizontal sectional view schematically illustrating an internal structure of the prober;

FIG. 3 is a cross-sectional view taken along arrows A-A in FIG. 2;

FIG. 4 is an enlarged diagram of part B in FIG. 3;

FIG. 5 is a diagram illustrating a configuration and operations of a measurement part;

FIG. 6 is a diagram illustrating a configuration and operations of the measurement part;

FIGS. 7A and 7B are diagrams illustrating an outline of a negative pressure control method during probing;

FIGS. 8A and 8B are graphs showing results of experiments conducted for setting a differential pressure correction value;

FIG. 9 is a flowchart illustrating an outline of a probing process;

FIG. 10 is a flowchart illustrating the outline of the probing process;

FIGS. 11A to 11F are diagrams illustrating the operation of the prober in the probing process;

FIGS. 12A to 12C are diagrams illustrating the operation of the prober in the probing process; and

FIGS. 13A and 13B show an advantageous effect of differential pressure correction according to the embodiment.

### DETAILED DESCRIPTION

An embodiment of the present invention will be described with reference to the drawings. In the following embodiment and modifications thereof, components that are substantially the same will be designated by the same reference numerals and redundant description thereof may be omitted as appropriate.

The description is not intended to limit the scope of the invention, but to exemplify the invention.

A prober according to an embodiment tests the electrical characteristics of semiconductor devices (also simply referred to as “devices”) formed on each wafer. For probing (wafer-level testing) in a low-temperature environment, dry air is supplied to respective areas of the prober to prevent dew condensation in the areas. During probing, an enclosed space is formed between a chuck holding a wafer and a test head. The negative pressure state in the enclosed space allows the chuck to be stably supported by the test head and the contact state between devices and probes to be maintained. The negative pressure is kept at a set pressure by a regulator provided externally. In the embodiment, dry air for preventing dew condensation is also supplied into the enclosed space. The set pressure is corrected depending on the flow rate of dry gas flowing into the enclosed space so as to stably prevent occurrence of dew condensation in the enclosed space. This will be described in detail hereinafter.

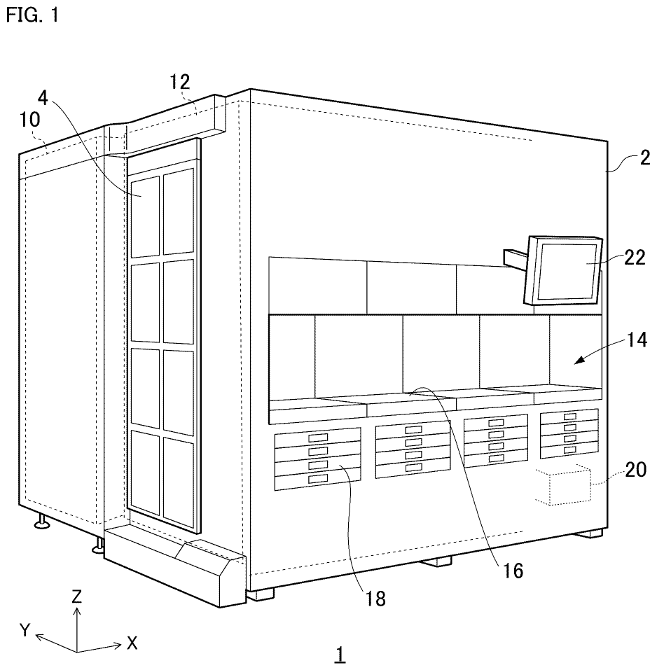

FIG. 1 is a diagram illustrating a schematic configuration of a prober according to an embodiment.

Hereinafter, for convenience of description, the left-right directions, the front-back directions, and the up-down directions when the machine is viewed from the front will be referred to as an X-axis direction, a Y-axis direction, and a Z-axis direction, respectively.

The prober 1 has a housing 2 having a rectangular shape in front view and in plan view. In the housing 2, a measurement area 10 in which each wafer is tested, and a loader area 12 through which wafers, etc. are conveyed into and from the measurement area 10 are located. The loader area 12 includes an accommodating area 14 in which wafers and probe cards are accommodated.

The accommodating area 14 includes a wafer storage part 16 for accommodating wafers and a card storage part 18 for accommodating probe cards. The wafer storage part 16 accepts wafer cassettes, such as FOUPS and FOSBS, accommodating a plurality of wafers. A worker or a robot can reach wafers or probe cards to be collected from the front side of the respective storages. A loader door 4 through which the worker goes into and out of the loader area is provided on a side face of the housing 2.

The prober 1 also includes a controller 20 and an operation panel 22. The controller 20 is constituted by a general-purpose computer including a CPU for executing various computation processes, a memory or a storage for storing control programs and the like, a memory to be used as a work area for data storage and program execution, an input/output interface, a user interface, and the like. The user interface receives operations input through the operation panel 22 by an operator. The controller 20 controls respective functional units (mechanisms and devices) of the prober 1 in accordance with control programs.

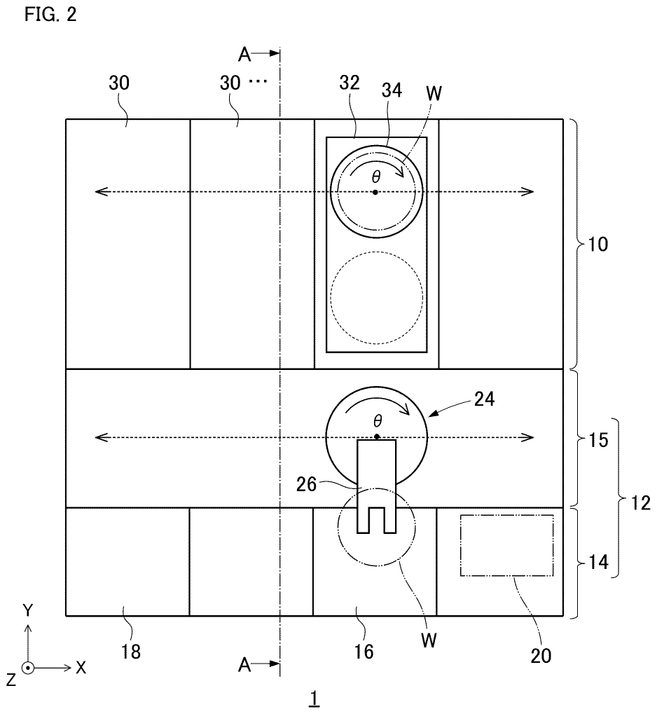

FIG. 2 is a horizontal sectional view schematically illustrating an internal structure of the prober 1.

The prober 1 includes the measurement area 10 and the loader area 12. The measurement area 10 includes the test area, which will be described later. The measurement area 10 and the loader area 12 are partitioned with a partition wall inside the housing 2. The loader area 12 includes the accommodating area 14 and a conveyance area 15. In the conveyance area 15, a conveyance unit 24 for conveying wafers W and probe cards (to be described later) is movably arranged.

In the measurement area 10, a plurality of measurement parts 30 for probing of wafers W are installed. In the embodiment, a multi-stage prober in which three stages of four measurement parts 30 arranged horizontally are provided in the up-down direction is adopted. The number of horizontally arranged measurement parts 30 and the number of stages can be set as appropriate.

In the measurement area 10, an alignment unit 32 shared by the measurement parts 30 on all the stages is provided. The alignment unit 32 detachably supports a chuck 34 (wafer chuck). Each chuck 34 fixes a wafer W by sucking the wafer W with vacuum suction, for example, and is attached to and detached from a test head of a measurement part 30 in a probing process (details of which will be described later). The alignment unit 32 can move among the measurement parts 30 arranged horizontally. Each chuck 34 is movable in X, Y, and Z directions within the measurement area 10 by the operation of the alignment unit 32 and is rotatable about an axis in the Z direction (in a direction θ).

The conveyance unit 24 conveys each wafer between the wafer storage part 16 and each measurement part 30, and conveys each probe card between the card storage part 18 and each measurement part 30. The conveyance unit 24 has an arm 26 for passing each wafer W. The arm 26 has a suction pad, which is not illustrated, on an upper face thereof. The arm 26 holds a wafer W by vacuum suction of a rear face of the wafer W with the suction pad. The conveyance unit 24 is a conveyor shared by the measurement parts 30 on all the stages, being movable in the X direction and in the Z direction by the operation of a drive mechanism, which is not illustrated, and being rotatable about an axis in the Z direction (in the direction θ).

The conveyance unit 24 advances and retracts (extends and contracts) the arm 26 forward and backward by the operation of an arm driving mechanism, which is not illustrated. A wafer W in the wafer storage part 16 is taken out by the arm 26, and conveyed to a measurement part 30 by the conveyance unit 24. Furthermore, a wafer W after being tested is brought back to the wafer storage part 16 through a reversed path from a measurement part 30.

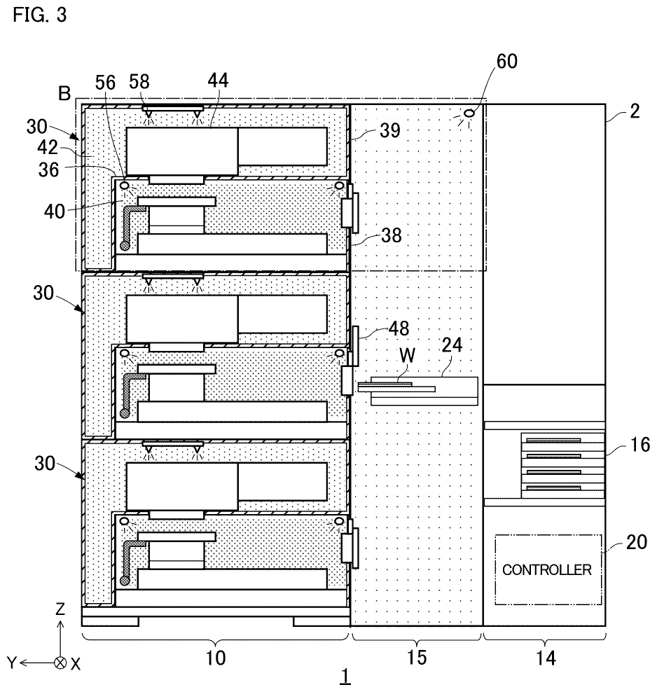

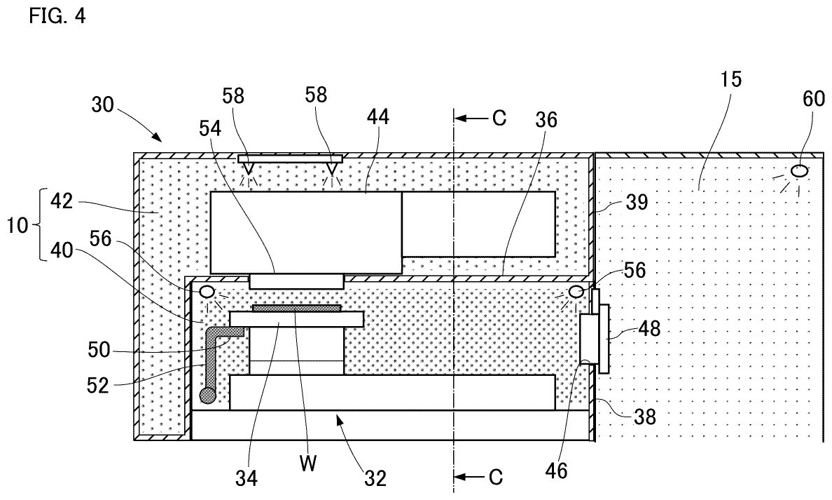

FIG. 3 is a cross-sectional view taken along arrows A-A in FIG. 2. FIG. 4 is an enlarged diagram of part B in FIG. 3.

As illustrated in FIG. 3, three stages of measurement parts 30 are provided in the up-down direction in the measurement area 10. Each measurement part 30 is defined by a partition 36 in a test area 40 and an equipment accommodating area 42. The test area 40 is an area in which a wafer W to be tested is placed, and is located at a relatively lower position. The equipment accommodating area 42 is an area in which a test head 44 and other electrical equipment are accommodated, and is located at a relatively higher position. The test area 40 is separated from the conveyance area 15 by a partition 38, and the equipment accommodating area 42 is separated from the conveyance area 15 by a partition 39. The equipment accommodating area 42 and the conveyance area 15 correspond to an “outer area” defined separately from the test area 40.

More specifically, as illustrated in FIG. 4, the alignment unit 32 is located in the test area 40. The partition 38 has an opening 46 through which the test area 40 and the conveyance area 15 communicate, and a shutter 48 for opening and closing the opening 46. When the shutter 48 is open, the arm 26 of the conveyance unit 24 can be advanced into the test area 40. That is, the wafer W can be passed between the conveyance unit 24 and the alignment unit 32.

In addition, in the test area 40, a heat exchanger 50 for cooling the chuck 34 is located. A pipe 52 for circulation of a coolant is connected to the heat exchanger 50. In a case where probing is performed in a low-temperature environment, the coolant is supplied to the chuck 34 through the pipe 52. This enables cooling of a wafer W (that is, devices formed on the wafer W) placed on the chuck 34.

The chuck 34 has, in the inside thereof, a heating and cooling unit (not illustrated). This enables heating or cooling of a wafer W to a high-temperature state (150° C., for example) or to a low-temperature state (−40° C., for example) for testing the electrical characteristics of devices on the wafer W. In the embodiment, a double layer structure including a heating layer of a planar heater and a cooling layer of a coolant passage is adopted as the heating and cooling unit. In a modification, a heater/cooler having a single layer structure in which a cooling pipe, around which a heater is wound, is embedded in a thermal conductor may be adopted as the heating and cooling unit.

In the equipment accommodating area 42, the test head 44 and electrical equipment, which is not illustrated, are located. At a boundary between the test area 40 and the equipment accommodating area 42, a pogo frame 54 is arranged. The pogo frame 54 functions as an interface connecting the test head 44 with the probe card (to be described later).

In each area, a discharge part for discharging dry air for preventing dew condensation is provided. A discharge part 56 is provided in the test area 40, and a discharge part 58 is provided in the equipment accommodating area 42. A discharge part 60 is also provided in the conveyance area 15.

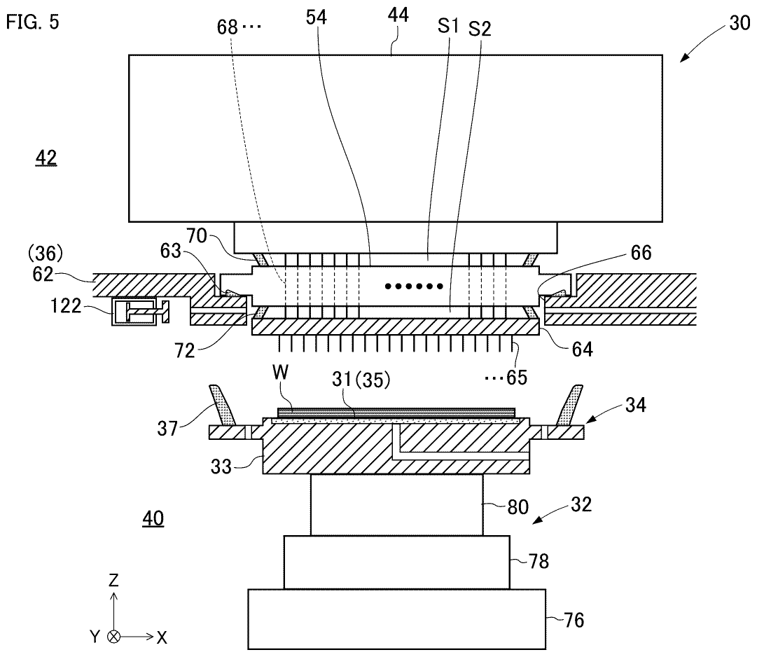

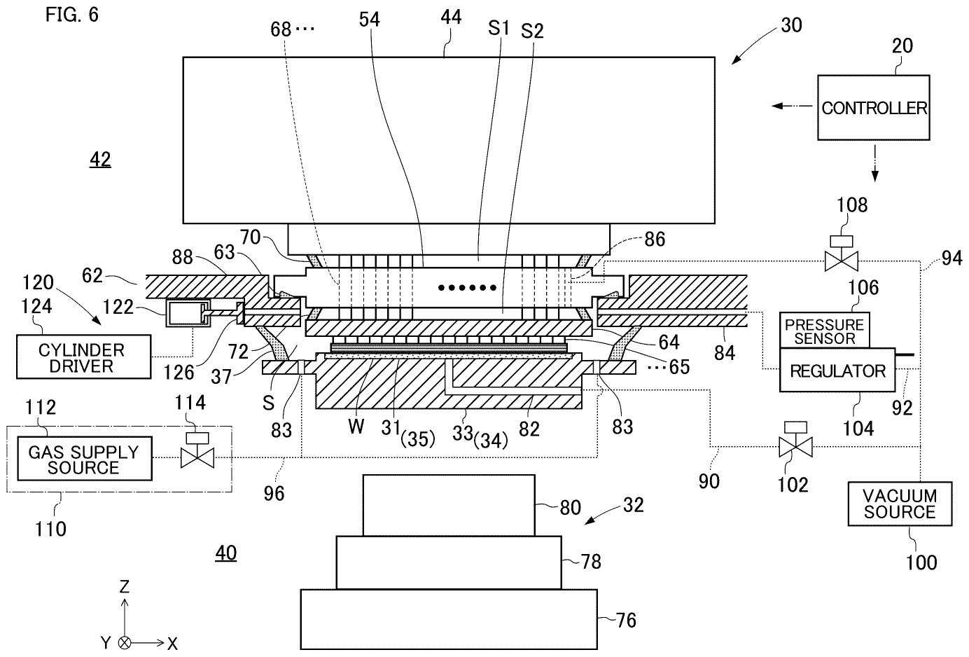

FIGS. 5 and 6 are diagrams illustrating a configuration and operations of a measurement part 30, and corresponding to a cross section along arrows C-C in FIG. 4. FIG. 5 shows a state before testing, and FIG. 6 shows a state during testing.

As illustrated in FIG. 5, each measurement part 30 includes a chuck 34, a test head 44, a pogo frame 54, a head stage 62, and a probe card 64. The probe card 64 includes a number of probes 65 for supplying power to a wafer W.

The pogo frame 54 and the head stage 62 constitute part of the partition 36, and functions as a “holding member” for holding the probe card 64. The head stage 62 has, at its center, a mounting hole 66 having a complementary shape (circular shape) for mounting the pogo frame 54. The pogo frame 54 is mounted to be fitted into the mounting hole 66, thus closing the mounting hole 66. The head stage 62 has a suction surface capable of sucking the pogo frame 54, and fixes the pogo frame 54 by sucking the pogo frame 54 with a vacuum source (a vacuum pump, for example), which will be described later. A seal ring 63 (sealing member) is arranged between the head stage 62 and the pogo frame 54 to keep airtightness therebetween. In a modification, however, the head stage 62 and the pogo frame 54 may be fixed by a fixing structure such as screws.

The test head 44 is supported above the head stage 62. The test head 44 is electrically connected with the probes 65 of the probe card 64, supplies test signals (electrical signals) to respective devices on the wafer W during testing, and detects signals output from the respective devices to obtain electrical characteristics thereof. In this manner, whether the respective devices work properly is tested.

The pogo frame 54 has a number of pogo pins 68 for electrically connecting terminals formed on a lower face (a face facing the pogo frame 54) of the test head 44 with terminals formed on an upper face (a face facing the pogo frame 54) of the probe card 64. In addition, seal rings 70 and 72 (sealing members) are arranged on peripheral edges of an upper face (a face facing the test head 44) and a lower face (a face facing the probe card 64), respectively, of the pogo frame 54. The seal ring 72 is located between the pogo frame 54 and the probe card 64, and functions as a “second sealing member”.

According to this configuration, a space S1 surrounded by the test head 44, the pogo frame 54, and the seal ring 70 and a space S2 surrounded by the probe card 64, the pogo frame 54, and the seal ring 72 are formed. When the spaces S1 and S2 are reduced in pressure to have negative pressures as described below, the test head 44, the pogo frame 54, and the probe card 64 are integrated. The space S1 and the space S2 correspond to “second enclosed spaces” in which the pogo pins 68 are located.

Furthermore, an inner space (that is, the test area 40) and an outer space (that is, the equipment accommodating area 42) are separated from each other by the partition 36 including the head stage 62 and the pogo frame 54. Note that, in the embodiment, even when the probe card 64 is removed from the pogo frame 54 for replacement of the probe card 64, the function of the seal ring 70 maintains the the test area 40 and the equipment airtightness between accommodating area 42.

The probe card 64 has a plurality of probes 65 for electrodes of the respective devices on the wafer W to be tested. When the test head 44, the pogo frame 54, and the probe card 64 are integrated as described above, the probes 65 are electrically connected with the terminals of the test head 44 via the pogo frame 54. The probe card 64 includes a number of probes 65 for the electrodes of all the devices on the wafer W to be tested, and all the devices on the wafer W are simultaneously tested in the measurement part 30.

The chuck 34 has a suction surface 31 for vacuum suction of the wafer W on its face facing the probe card 64. More specifically, the chuck 34 includes a disc-shaped chuck body 33 and a disc-shaped holder 35 mounted on a top face of the chuck body 33. The holder 35 is a porous member made of ceramics or the like. The top face of the holder 35 is the suction surface 31 for holding a wafer W by suction. A chuck sealing rubber 37 (seal ring) is arranged on the top face of the chuck body 33 to surround the wafer W. The chuck sealing rubber 37 functions as a “first sealing member”.

The chuck 34 is detachably supported by the alignment unit 32. The alignment unit 32 includes an X table 76, a Y table 78, and a Z table 80. A guide rail extending in the X direction is provided in the measurement area 10 of the housing 2 (see FIG. 3), and the X table 76 is horizontally arranged to be movable in the X direction along the guide rail. The X table 76 is driven by a moving mechanism, which is not illustrated. A guide rail extending in the Y direction is provided on an upper face of the X table 76. The Y table 78 is horizontally arranged to be movable in the Y direction along the guide rail. The Y table 78 is driven by a moving mechanism, which is not illustrated. Each moving mechanism may be constituted by a feed screw mechanism and a servomotor that drives the feed screw mechanism, or may be constituted by a linear motor.

The Z table 80 is supported to be movable, up and down, in the Z direction and rotatable in the direction θ by the Y table 78. The Z table 80 is provided with a lifting mechanism for moving the chuck 34 up and down and a rotating mechanism for rotating the chuck 34 (which are not illustrated). The rotating mechanism is constituted by a spindle motor, for example. The chuck 34 is detachably supported by an upper face of the Z table 80. This configuration allows the chuck 34 to be moved in each of the X direction, the Y direction, the Z direction, and the direction θ. Movement of the chuck 34 enables the wafer W to be positioned relative to the probe card 64.

As also illustrated in FIG. 6, in a probing process, the Z table 80 is moved to move the chuck 34 (upward) toward the probe card 64. In this process, the chuck sealing rubber 37 comes into contact with a lower face of the head stage 62, and an enclosed space S surrounded by the chuck 34, the probe card 64, the head stage 62, and the chuck sealing rubber 37 is thus formed. The chuck sealing rubber 37 is located between the head stage 62 and the chuck 34. The enclosed space S corresponds to a “first enclosed space”, which is included in the test area 40 and in which the probes 65 are arranged.

The chuck body 33 includes a suction passage 82 for vacuuming a wafer W mounted on the suction surface 31. The suction passage 82 is connected with a vacuum source 100 via a pipe 90. The vacuum source 100 is driven to perform vacuuming by causing a suction force reaching the wafer W through the porous structure of the holder 35. The wafer W is sucked onto the suction surface 31 by a negative pressure generated in this process. The pipe 90 is provided with a regulating valve 102. The regulating valve 102 adjusts the suction force (negative pressure) to be applied onto the suction surface 31 of the chuck 34. While the regulating valve 102 according to the embodiment is an electromagnetic valve driven by a solenoid, the regulating valve 102 may be a motor-driven valve. The controller 20 controls the operation of the regulating valve 102.

The head stage 62 (holding member) includes a suction passage 84 that communicates with the enclosed space S. The suction passage 84 is connected with the vacuum source 100 via a pipe 92 (external pipe). The pipe 92 is provided with a regulator 104 and a pressure sensor 106. The regulator 104 is an electro-pneumatic regulator that adjusts the flow of fluid through the pipe 92 so that the negative pressure acting in the enclosed space S (first enclosed space) becomes closer to a set pressure. The regulator 104 is installed outside the housing 2 (that is, in normal temperature environment) to avoid the influence of temperature changes in the prober 1 so as to keep normal operation.

The pressure sensor 106 detects the internal pressure of the regulator 104, that is, the pressure adjusted by the regulator 104. The controller 20 functions as a “pressure controller”, calculates a set value of the negative pressure (set pressure) acting in the enclosed space S, and outputs a pressure control command to the regulator 104. Upon receiving the control command, the regulator 104 autonomously operates so that the internal pressure, and thus the negative pressure in the enclosed space S, become closer to the set pressure. Specifically, the controller 20 performs feedback control to make the deviation between a “target pressure”, which is the set pressure and an “actual pressure”, which is the pressure detected by the pressure sensor 106, closer to zero.

The pogo frame 54 includes a suction passage 86 that communicates with the spaces S1 and S2. The suction passage 86 is connected with the vacuum source 100 via a pipe 94. The pipe 94 is provided with a regulating valve 108. The regulating valve 108 adjusts the suction force (negative pressure) to be applied to the spaces S1 and S2 (second enclosed spaces). While the regulating valve 108 according to the embodiment is an electromagnetic valve, the regulating valve 108 may be a motor-driven valve. The controller 20 controls the operation of the regulating valve 108.

The prober 1 further includes a gas supply part 110 for supplying dry air to the enclosed space S (first enclosed space). The gas supply part 110 includes a gas supply source 112 and a flow control valve 114. The chuck 34 includes a gas supply passage 83 that communicates with the enclosed space S. The gas supply passage 83 is connected with the gas supply source 112 via a pipe 96. Dry air supplied from the gas supply source 112 is discharged into the enclosed space S from an open end of the gas supply passage 83 (that is, the surface of the chuck 34).

The pipe 96 is provided with the flow control valve 114. While the flow control valve 114 according to the embodiment is an electromagnetic valve, the flow control valve 114 may be a motor-driven valve. The gas supply source 112 has a tank for storing pressurized dry air. The flow control valve 114 adjusts the flow rate of dry air supplied from the gas supply source 112 into the enclosed space S. During probing, the controller 20 controls the opening degree of the flow control valve 114 to control the flow rate of dry air.

The vacuum source 100 and the regulator 104 operate to reduce the pressure in the enclosed space S, and the chuck 34 is therefore drawn toward the probe card 64. Because the enclosed space S has a negative pressure, the airtightness of the enclosed space S sealed by the chuck sealing rubber 37 is achieved, and the chuck 34 is held by the head stage 62. In addition, the probes 65 of the probe card 64 come into contact with the respective devices on the wafer W, and testing can be conducted.

At this point, the Z table 80 can be separated from the chuck 34 as illustrated, so that the alignment unit 32 can be used for another measurement part 30. As described above, the alignment unit 32 is shared by the measurement parts 30 on all the stages, a wafer W can be passed in a measurement part 30 while testing is being performed in another measurement part 30.

Furthermore, the head stage 62 (holding member) has a communication passage 88 through which the enclosed space S communicates with the external space (the test area 40). An opening/shutting mechanism 120 for opening and closing the communication passage 88 is provided. The opening/shutting mechanism 120 includes an air cylinder 122 and a cylinder driver 124. The cylinder driver 124 drives the air cylinder 122 to operate a shutter 126 to thereby open and close the communication passage 88. The controller 20 controls the cylinder driver 124.

For starting probing, the communication passage 88 is closed to enable vacuuming of the enclosed space S. At the end of probing, the communication passage 88 is opened so that the negative pressure in the enclosed space S can be released. This allows the chuck 34 to be quickly separated from the head stage 62.

Next, a method for preventing dew condensation according to the embodiment will be described in detail.

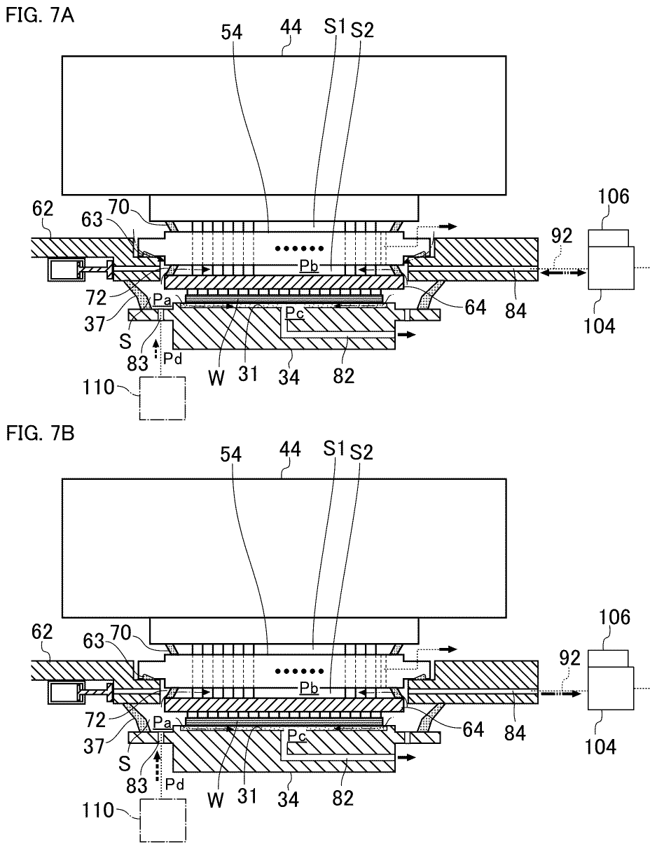

FIGS. 7A and 7B are diagrams illustrating an outline of a negative pressure control method during probing. FIG. 7A shows a state in which the negative pressure in the enclosed space S is instable, and FIG. 7B shows a state in which the negative pressure in the enclosed space S is stable.

As shown in FIG. 7A, the set value of the negative pressure Pa in the enclosed space S during probing is set to a value (set pressure P) appropriate for holding the chuck 34. The regulator 104 autonomously operates so that the negative pressure Pa becomes the set pressure P. Note that the set pressure P is smaller than both of the negative pressure Pb acting in the space S2 (second enclosed space) adjacent to the enclosed space S and the negative pressure Pc acting in the suction surface 31 of the chuck 34.

In the embodiment, the negative pressure Pa is set to −5 kPa, the negative pressure Pb is set to −60 kPa, and the negative pressure Pc is set to −90 kPa. This is in view of the possibility that the probe card 64 may come off the pogo frame 54 when the negative pressure Pa is greater than the negative pressure Pb and the possibility that the wafer W may come off the suction surface 31 when the negative pressure Pa is greater than the negative pressure Pc.

In the embodiment, the set pressure P is calculated by the following formula (1):

$$P = ( \frac{k \times N}{1000 \times 100} \times {Z}_{O D} + M ) \times 9.8 \times \frac{1000}{A} + P 1 \qquad ( 1 )$$

where k represents the spring constant (gf/100 μm) of the probes, N represents the number of probes, Z_{OD} represents the overdrive (μm) of the prober relative to the electrode of the wafer W, M represents the weight (kgf) of the chuck, A represents the suction area (mm²) of the chuck, and P1 represents a differential pressure correction value (kPa).

In the formula (1), k, N, Z_{OD}, M, and A included in the terms before the differential pressure correction value P1 are parameters relating to the holding force of the chuck 34, which are also included in calculation of conventional set pressures. According to the embodiment, a conventional set pressure is corrected with the differential pressure correction value P1 so that the negative pressure in the enclosed space S is stably maintained. Specifically, for setting the differential pressure correction value P1, the following influences are considered as factors causing pressure fluctuation in the enclosed space S.

### 1. Influence of Dry Air Supply

As described above, dry air is supplied at a positive pressure Pd from the gas supply passage 83 to prevent dew condensation. The positive pressure Pd is a factor that reduces the negative pressure Pa in the enclosed space S. In other words, a loss of negative pressure is caused by the discharge pressure (positive pressure) of the dry gas into the enclosed space S.

2. Influence of Pressure Difference from Adjacent Areas

As described above, because the negative pressures Pb and Pc in the areas adjacent to the enclosed space S are significantly greater than the negative pressure Pa, the pressure in the enclosed space S may escape into the space S2 or toward the suction surface 31 with higher negative pressures, and the negative pressure Pa in the enclosed space S may become greater than the set pressure. As a result, the negative pressure Pa may not be consistent with the adjustment of the regulator 104, and the air may flow back from the regulator 104 side toward the enclosed space S.

Furthermore, although the seal ring 63 and the chuck sealing rubber 37 ensure sealing between the members forming the enclosed space S, if the negative pressure in the enclosed space S increases and the pressure difference from the outside thus increases, external air may enter the enclosed space S.

### 3. Influence of Pressure Loss

As described above, because the pipe 92 connecting the enclosed space S with the regulator 104 has a certain length, there is a significant distance between the enclosed space S and the pressure sensor 106. A certain delay therefore occurs in transmission of pressure changes in the enclosed space S to the regulator 104. There is also a pressure loss in the pipe 92 (more specifically, a pressure loss of fluid between the regulator 104 and the enclosed space S). The pressure adjustment performed by the regulator 104 may therefore be delayed or insufficient, and air may flow back from the regulator 104 side toward the enclosed space S.

In the embodiment, in view of the influences described above, the differential pressure correction value P1 is set so that fluid does not flow back from the pipe 92 to the enclosed space S during probing (while the regulator 104 and the gas supply part 110 are operating) as shown in FIG. 7B. In other words, the differential pressure correction value P1 for correcting the set pressure P as will be described later is set so as to reduce instability of the negative pressure in the enclosed space S due to the influences described above and stably prevent occurrence of dew condensation.

The differential pressure correction value P1 is set as a fixed value depending on the flow rate of dry air supplied to the enclosed space S, and determined experimentally in advance. As described above, there is a difference (differential pressure) between the pressure detected by the pressure sensor 106 and the actual pressure in the enclosed space S due to the influences described above. As a result, the control performed by the regulator 104 may be deviated owing to the differential pressure. The differential pressure changes with the flow rate of the dry air (the discharge pressure of dry air into the enclosed space S).

In the embodiment, to avoid the influences, the differential pressure correction value P1 based on the differential pressure is set and reflected in the setting of the set pressure P. Note that the flow rate of dry air is determined so that the supply of dry air is ensured against the differential pressure. Specifically, the gas supply part 110 adjusts the flow rate of dry air to a predetermined flow rate of 1 L/min or higher. The predetermined flow rate is set within a range in which the absolute value of the discharge pressure of dry air is smaller than the absolute value of the set pressure P. In other words, the flow rate is set within a range that does not affect the suction (vacuum contact) between the chuck 34 and the head stage 62 caused by the negative pressure in the enclosed space S.

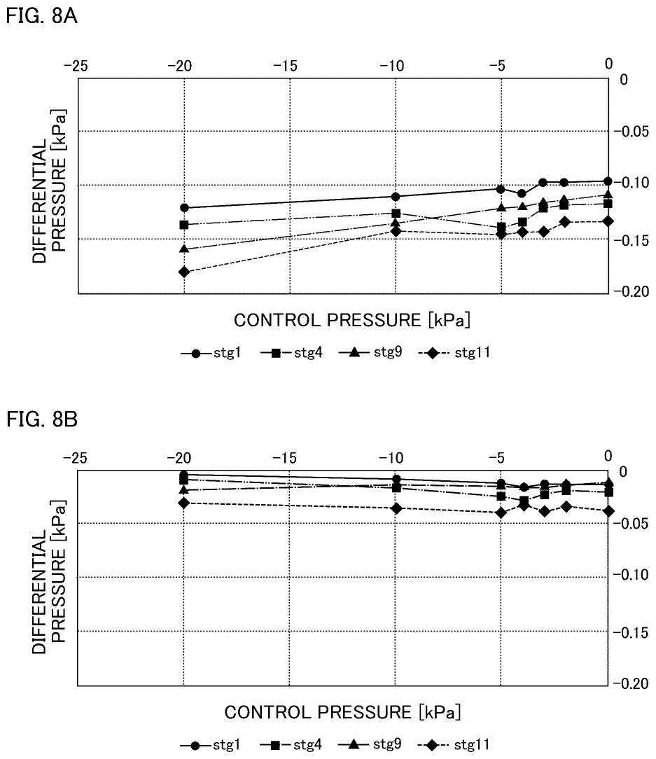

FIGS. 8A and 8B are graphs showing results of experiments conducted for setting the differential pressure correction value. FIG. 8A shows a case (with purging) where dry air was supplied to the enclosed space S, and FIG. 8B shows a case (without purging) where dry air was not supplied to the enclosed space S.

In an experiment for determining the differential pressure correction value P1, pressures detected by the pressure sensor 106 for the regulator 104 and pressures detected by a pressure sensor tentatively installed in the chamber (enclosed space S) were measured, and differential pressures therebetween were plotted. In addition, a condition with purging with dry air at 1100 mL/min (FIG. 8A) and a condition without the purging (FIG. 8B) were set. This purging amount was set to include a slight margin with respect to 1 L/min. Note that the actual working pressure (negative pressure) in the enclosed space S was assumed to be a pressure closer to the atmospheric pressure than-10 kPa.

Because a multi-prober was used for the experiment, the same experiment was performed on a plurality of chucks (stages: stg). As a result, the variation in differential pressures measured for the respective chucks was up to 40 Pa. In a case of a specification with an overdrive of 100 μm at 4 kPa, the pressure difference was equivalent to 2 μm, which was small. As compared with the condition without purging, however, the pressure difference was 125 Pa. This is equivalent to 6 μm in the case of the aforementioned specification, which is insufficient for the precision of the overdrive. Therefore, for calculation of the set pressure P, 125 Pa was added as the differential pressure correction value P1 to correct the overdrive to be closer to a theoretical overdrive.

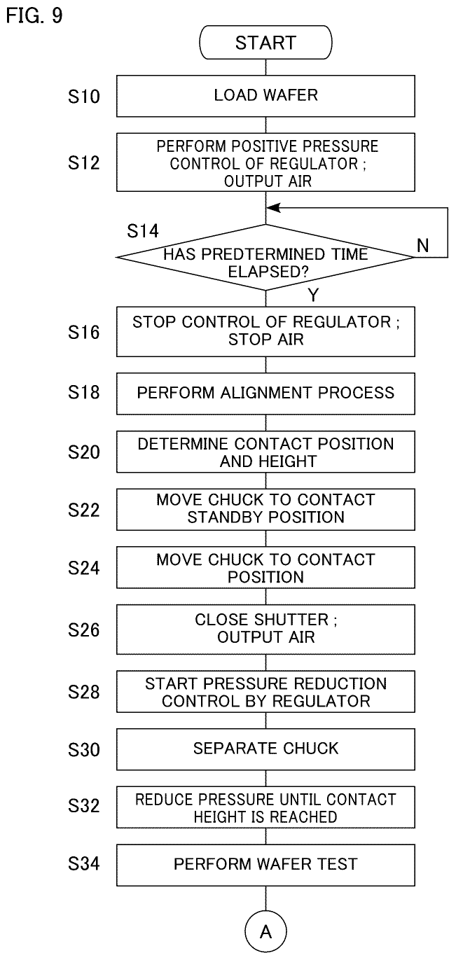

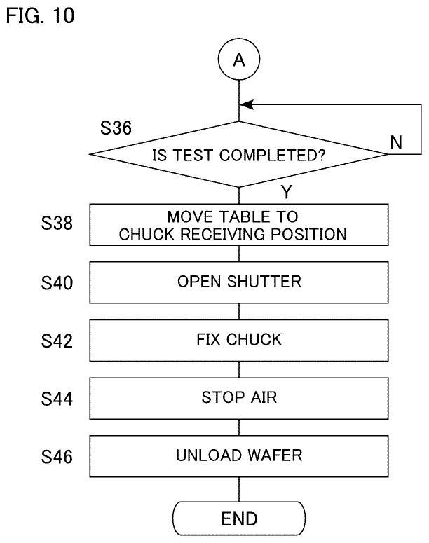

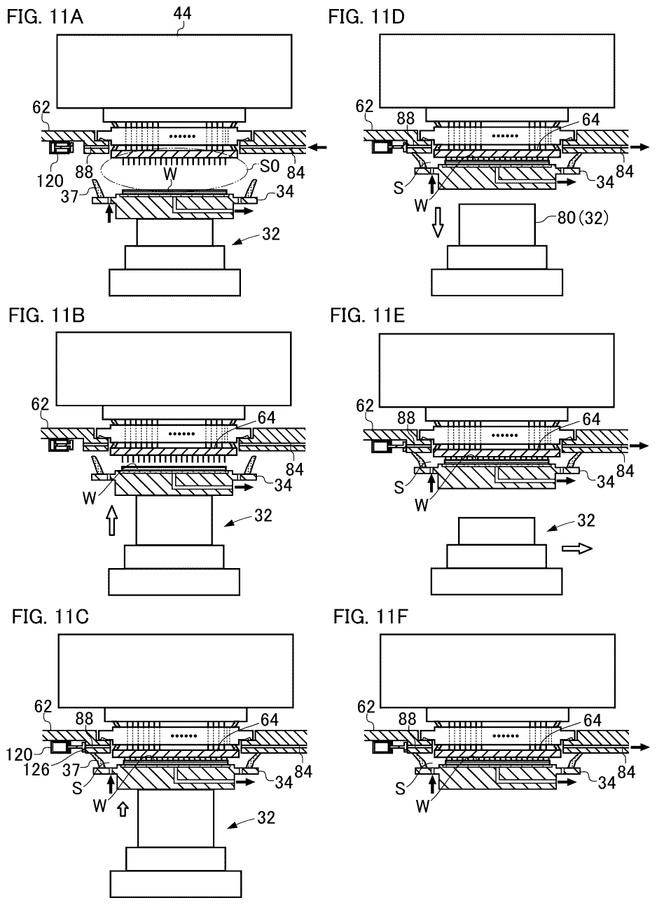

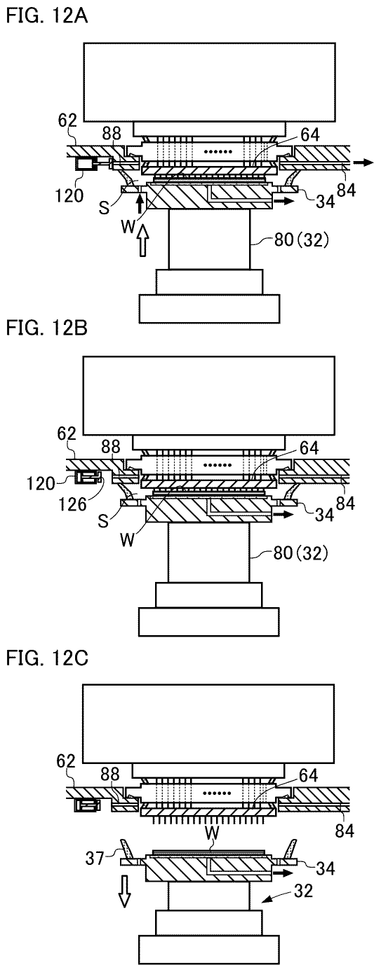

FIGS. 9 and 10 are flowcharts illustrating an outline of a probing process. FIGS. 11A to 11F and FIGS. 12A to 12C are diagrams illustrating the operation of the prober 1 in the probing process. FIGS. 11A to 11F show processing steps from the start of the probing process until probing is actually performed, and FIGS. 12A to 12C show processing steps after testing is completed. Hereinafter, the flow of the probing process will be described on the basis of FIGS. 9 and 10, and with reference to FIGS. 11A to 11F and FIGS. 12A to 12C as necessary.

As shown in FIG. 9, the controller 20 first loads a wafer W onto a chuck 34 supported by the alignment unit 32 (S10) and performs positive pressure control of the regulator 104 and supply of dry air (S12: FIG. 11A). At this point, the vacuum source 100 is driven to suck the wafer W onto the chuck 34. The chuck 34 is spaced apart from the head stage 62, and an open space S0 is thus formed between the chuck 34 and the head stage 62. The communication passage 88 is open.

The controller 20 drives the gas supply part 110 to supply dry air into the open space S0 for a predetermined time (about 3 seconds, for example) so as to dry the atmosphere around the chuck 34. The regulator 104 is set to a positive pressure to prevent the moisture removed in this process from being drawn toward the vacuum source 100. In other words, the gas in the pipe 92 is blown out toward the open space S0.

After the predetermined time has elapsed (Y in S14), the controller 20 temporarily stops the control of the regulator 104 and the driving of the gas supply part 110 (S16), and drives the alignment unit 32 to perform an alignment process (S18). Specifically, the alignment unit 32 adjusts the positions of the wafer W in the horizontal direction (XY direction) and in the rotation direction (θ direction) so that devices on the wafer W respectively face the probes 65.

Subsequently, the controller 20 drives the alignment unit 32 to determine the position and height of contact with the devices in view of the overdrive of the probes 65 (S20). Thereafter, the alignment unit 32 moves the chuck 34 to a standby position directly below the probe card 64 (S22: FIG. 11B), and then moves the chuck 34 to the contact position (S24: FIG. 11C).

Subsequently, the controller 20 drives the opening/shutting mechanism 120 to cause a closing operation of the shutter 126 to close the communication passage 88, and drives the gas supply part 110 to start supply of dry air into the enclosed space S (S26: FIG. 11C). The controller 20 also starts pressure reduction control on the enclosed space S by the regulator 104 (S28). Specifically, before a negative pressure is supplied into the enclosed space S, the communication passage 88 is closed and supply of dry gas is started. The controller 20 then separates the chuck 34 from the Z table 80 of the alignment unit 32 (S30), and reduces the pressure in the enclosed space S while correcting the set pressure P with the differential pressure correction value P1 (performing differential pressure correction) until the wafer W reaches the contact height (that is, until the set overdrive is reached) (S32: FIG. 11D).

The alignment unit 32 from which the chuck 34 has been separated moves to another measurement part 30 (FIG. 11E). The controller 20 performs testing (wafer test) with the test head 44 (S34: FIG. 11F). In this process, as described above, correction of the set pressure P (differential pressure correction) with the differential pressure correction value P1 is performed. The controller 20 performs the wafer test while continuing control of the regulator 104 based on the corrected set pressure P.

As shown in FIG. 10, when the wafer test is complete (Y in S36), the controller 20 moves the Z table 80 of the alignment unit 32 to a position for receiving the chuck 34 (S38: FIG. 12A). The controller 20 drives the opening/shutting mechanism 120 to cause an opening operation of the shutter 126 to open the communication passage 88 (S40), and fixes the chuck 34 to the Z table 80 (S42: FIG. 12B). Subsequently, the controller 20 stops the supply of dry air (S44).

Specifically, for releasing the airtightness of the enclosed space S, the communication passage 88 is opened, and the supply of dry gas is stopped thereafter. Subsequently, the chuck 34 is retracted from the head stage 62, and the wafer W is unloaded from the chuck 34 (S46: FIG. 12C).

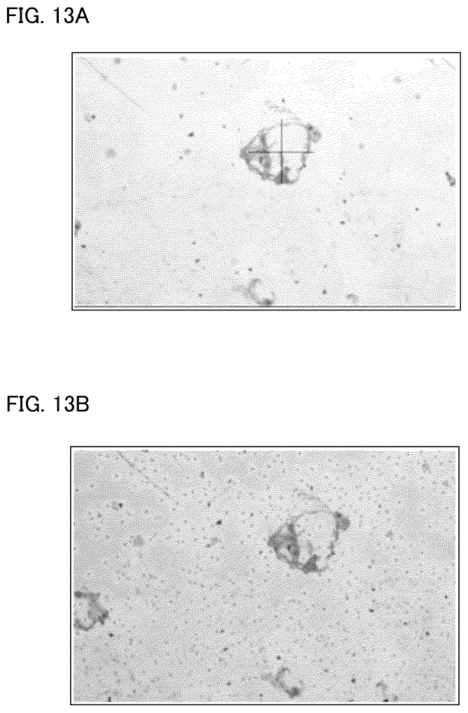

FIGS. 13A and 13B show an advantageous effect of differential pressure correction according to the embodiment. FIG. 13A is an enlarged photograph of a specific position on the surface of a wafer in a case where the differential pressure correction was performed. FIG. 13B is an enlarged photograph of the same position on a wafer in a case where the differential pressure correction was not performed according to a comparative example.

As is clear from comparison between FIG. 13A and FIG. 13B, numerous (scattered) ice formations due to dew condensation are observed on the wafer W in the comparative example (FIG. 13B). In contrast, such ice formations do not appear in the embodiment (FIG. 13A). The advantageous effect of the differential pressure correction according to the embodiment can be observed.

As described above, according to the embodiment, for probing in a low-temperature environment, dry air is supplied into the enclosed space S in which the wafer W and the probes 65 are arranged. This prevents or minimizes dew condensation on the wafer W or electrodes of the probes 65. In particular, because the space S2 and the suction passage 82 with negative pressures greater than that in the enclosed space S are located adjacent to the enclosed space S, the negative pressure in the enclosed space S is likely to be greater than a set value owing to the influences of the adjacent negative pressures. In addition, a positive pressure of dry air is supplied. This makes the negative pressure in the enclosed space S easily fluctuate. In this regard, the set pressure P is corrected with the differential pressure correction value P1 in view of these influences. As a result, fluid flowing from an external pipe to the enclosed space S is prevented from flowing back, and dew condensation due to pressure fluctuation in the enclosed space S is also prevented. This allows stable prevention of occurrence of dew condensation during probing.

A certain embodiment has been described above. It should be obvious that the present invention is not limited to the embodiment and various modifications could be further developed within the technical idea underlying the present invention.

### Modifications

In the embodiment described above, an example in which the regulator 104 is provided with the pressure sensor 106 has been presented. The pressure sensor 106 may be installed externally to the regulator 104, or may be built in the regulator 104. Alternatively, the pressure sensor 106 may be independent from the regulator 104 and installed in the vicinity of the regulator 104 in the pipe 92.

While an example in which dry air is used as the dry gas has been presented in the embodiment, a dry inert gas or other dry gases may be used.

While an example of the multi-stage prober including a plurality of measurement parts 30 has been presented in the embodiment, a single-stage prober including a single measurement part 30 may be used. In this case, in a manner similar to the embodiment, the controller controls the flow rates of dry gas so that the dew points become the set dew points in the respective areas.

In the embodiment described above, an example in which the number of probes 65 included in the probe card 64 corresponds to the number of all devices on a wafer W and all the devices on the wafer W are simultaneously tested has been presented. In a modification, a configuration in which the number of probes included in a probe card corresponds to the number of some of devices on a wafer and the devices on the wafer are sequentially tested may be adopted.

Although not mentioned in the embodiment, the pipes 90, 92, and 94 may be individually connected with the vacuum source 100 illustrated in FIG. 6.

While measures against dew condensation on a wafer W have been mainly described in the embodiment, similar dew condensation prevention effects can also be produced for the probe card 64.

While probing mainly in a low-temperature environment has been described in the embodiment, it is needless to say that testing can also be performed at a plurality of temperature levels from a low temperature to a high temperature.

The present invention is not limited to the embodiments described above and modifications thereof, and any component thereof may be modified and embodied without departing from the scope of the invention. Components described in the embodiments and modifications may be combined as appropriate to form various embodiments. Some components may be omitted from the components presented in the embodiments and modifications.

What is claimed is:

1. A prober comprising:
a holding member that holds a probe card;
a chuck having a suction surface for vacuum suction of a wafer on a face facing the probe card;
a sealing member that is located between the holding member and the chuck and forms an enclosed space in which probes connected with the probe card are arranged;
a suction passage connected with a vacuum source via an external pipe to reduce a pressure in the enclosed space;
a regulator that is connected with the external pipe, and adjusts a flow of fluid through the external pipe so that a negative pressure acting in the enclosed space becomes closer to a set pressure;
a gas supply part that supplies dry gas into the enclosed space; and
a pressure controller that controls the regulator,
wherein the enclosed space is brought into a negative pressure state, so that airtightness of the enclosed space sealed by the sealing member is achieved and the chuck is held by the holding member,
wherein the gas supply part supplies dry gas while the regulator is operating, and
wherein the pressure controller corrects the set pressure depending on a flow rate of the dry gas so as to prevent the fluid from flowing back from the external pipe to the enclosed space while the regulator and the gas supply part are operating.

2. The prober according to claim 1, further comprising:
a first sealing member, being the sealing member, that forms a first enclosed space being the enclosed space; and
a second sealing member that is located between the holding member and the probe card inside the first enclosed space, and forms a second enclosed space in which pogo pins connected with the probe card are arranged,
wherein the set pressure is set to a negative pressure smaller than both of a negative pressure acting in the second enclosed space and a negative pressure acting on the suction surface.

3. The prober according to claim 1, wherein the gas supply part adjusts the flow rate of the dry gas to a predetermined flow rate of 1 L/min or higher.

4. The prober according to claim 3, wherein the predetermined flow rate is set within a range in which an absolute value of a discharge pressure of dry gas is smaller than an absolute value of the set pressure.

5. The prober according to claim 1, wherein the pressure controller corrects the set pressure on the basis of a discharge pressure of dry gas discharged by the gas supply part.

6. The prober according to claim 5, wherein the pressure controller corrects the set pressure on the basis of a pressure loss of fluid between the regulator in the external pipe and the enclosed space.

7. The prober according to claim 1, further comprising:
a communication passage through which a test area containing the enclosed space communicates with the enclosed space; and
an opening/shutting mechanism that opens and closes the communication passage,
wherein the opening/shutting mechanism closes the communication passage before a negative pressure is supplied into the enclosed space, and
wherein the gas supply part starts supply of dry gas before the negative pressure is supplied into the enclosed space.

8. The prober according to claim 7,
wherein, for releasing airtightness of the enclosed space, the opening/shutting mechanism opens the communication passage, and
wherein the gas supply part stops supply of dry gas after the communication passage is opened.
